(19) United States
(12) Patent Application Publication
(10) Pub. No.: US 2025/0271492 A1
(43) Pub. Date: Aug. 28, 2025

(54) MEASUREMENT SYSTEM FOR ACTIVE LOAD PULL TESTING AND ACTIVE LOAD PULL MEASUREMENT METHOD

(71) Applicant: Rohde & Schwarz GmbH & Co. KG, Muenchen (DE)

(72) Inventors: Florian RAMIAN, Muenchen (DE); Thilo BEDNORZ, Muenchen (DE)

(21) Appl. No.: 19/013,531

(22) Filed: Jan. 8, 2025

(30) Foreign Application Priority Data
Feb. 28, 2024 (EP) 24 160 272.1

(51) Int. Cl. G01R 31/28; G01R 35/00

(52) U.S. Cl. CPC G01R 31/2822; G01R 35/005

(57) ABSTRACT

A measurement system includes a signal analysis circuit, a signal generator circuit, a control circuit, and a DUT connector. The DUT connector is connectable to a device under test for receiving a measurement signal outputted by the DUT. The signal analysis circuit is connected to the DUT connector for receiving the measurement signal. The signal generator circuit is configured to generate a radio frequency (RF) test signal that is transmitted to the DUT. The signal analysis circuit is configured to digitize the measurement signal, thereby obtaining a digitized measurement signal. The control circuit is configured to control the signal generator circuit to generate the RF test signal based on the digitized measurement signal, based on known error parameters of an error model of the measurement system, and based on a desired reflection coefficient at a reference plane associated with the DUT.

### CROSS-REFERENCE TO RELATED APPLICATION

This application claims priority from European Patent Application No. 24 160 272.1, filed on Feb. 28, 2024, the entire disclosure of which is incorporated herein in its entirety.

### FIELD OF THE DISCLOSURE

Embodiments of the present disclosure generally relate to a measurement system for active load pull testing. Embodiments of the present disclosure further relate to an active load pull measurement method.

### BACKGROUND

Certain types of electronic devices under test, for example power amplifiers, need to be tested at a given impedance or over a given range of impedances.

Typically, measurement instruments are constructed for measurements at one specific impedance, which usually is 50 Ohm.

There are different techniques for adjusting the impedance. For example, the impedance presented to the device under test can be adjusted by a mechanical tuner, which is also known as a “passive load pull” technique.

As another example, the impedance presented to the device under test can be adjusted by measuring a signal received from the device under test and a signal transmitted to the device under test with two measurement receivers, and by generating a signal that is applied to the device under test based on the measured signals, such that a desired impedance is presented to the device under test.

The known techniques described above require extra hardware in order to be performed compared to the usual measurement operations performed by the measurement instrument.

Thus, there is a need for a measurement system for active load pull testing and an active load pull measurement method that have reduced hardware requirements.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a measurement system for active load pull testing. In an embodiment, the measurement system comprises a signal analysis circuit, a signal generator circuit, a control circuit, and a DUT connector. The DUT connector is connectable to a device under test in order to receive an output signal of the device under test. The signal analysis circuit is connected to the DUT connector such that the signal analysis circuit receives a measurement signal corresponding to the output signal. The signal generator circuit is configured to generate a radio frequency (RF) test signal. The signal generator circuit is connected to the DUT connector such that the RF test signal is applied to the device under test. The signal analysis circuit is configured to digitize the measurement signal, thereby obtaining a digitized measurement signal. The control circuit is configured to control the signal generator circuit to generate the RF test signal based on the digitized measurement signal, based on known error parameters of an error model of the measurement system, and based on a desired reflection coefficient at a reference plane associated with the device under test. The error model describes, for example, transmissivity, reflectivity, and/or directivity properties of the measurement system with respect to the reference plane.

The term “error parameters” is understood to denote parameters of the error model describing transmissivity, reflectivity, and/or directivity properties of a portion of the measurement setup including the reference plane.

The measurement system according to embodiments of the present disclosure is based on the idea to utilize the known error parameters of the error model in order to set the desired reflection coefficient at the reference plane. For example, the known error parameters may have been determined in a previous calibration, which has to be performed for conducting tests on the device under test anyway. Due to the utilization of the error model, it is not necessary to measure the RF test signal generated by the signal generator circuit. Instead, it is sufficient to measure the output signal of the device under test.

In an embodiment, the properties of the output signal at the reference plane can be determined based on the digitized measurement signal and based on the error model.

In an embodiment, the properties of the RF test signal transmitted at the reference plane can be determined based on the error model.

As the properties of the output signal of the device under test and of the RF test signal at the reference plane can be determined or calculated based on the error model, the appropriate RF test signal can be generated in order to present the desired reflection coefficient to the device under test at the reference plane.

In other words, by generating the RF test signal based on the digitized measurement signal, based on the known error parameters of the error model, and based on the desired reflection coefficient at the reference plane, a desired impedance can be presented to the device under test, i.e. the desired reflection coefficient is set at the reference plane.

Thus, fewer hardware components are necessary for active load pull measurements performed by the measurement system according to the present disclosure.

In an embodiment, one measurement receiver is sufficient in the signal analysis circuit in order to set the desired reflection coefficient at the reference plane. It is noted that, of course, the measurement system may comprise more than one measurement receiver. However, this is not necessary for the measurement system according to the present disclosure.

It is also noted that the measurement system may nonetheless comprise a passive load pull tuner, wherein the passive load pull tuner may be interconnected between the device under test and the DUT connector or may be provided between the DUT connector and the signal analysis circuit.

Generally, the reference plane may correspond to the plane at which the device under test is connected to the DUT connector. In some embodiments, a cable may be connected to the DUT connector, wherein the reference plane is located at an end of the cable facing away from the DUT connector. Thus, the error model describes transmissivity, reflectivity, and/or directivity properties of a portion of the measurement system including the DUT connector, the cable, and the reference plane. This way, the accuracy of a calibration and/or of subsequent measurements on the device under test can be enhanced, as connections within the measurement system, namely the cable, are taken into account in the error model.

According to an aspect of the present disclosure, the RF test signal, for example, is a modulated signal. Thus, the measurement system according to the present disclosure is also suitable for modulated S-parameter measurements.

Therein and in the following, the term “modulated signal” is understood to denote a signal with an amplitude, frequency and/or phase that is adapted over time. In other words, the modulated signal is not a pure continuous wave (CW) signal. For example, the modulated signal may be a frequency sweep signal, wherein the frequency of an CW signal is adapted according to a predefined periodic function such as a sawtooth function.

In an embodiment, the error model is an n-term error model, for example a 4-term error model or an 8-term error model. Accordingly, the error model comprises n error parameters that need to be determined in order to calibrate the measurement system, i.e. the error terms comprise a total of n error parameters.

N is an integer greater than 1, for example equal to or greater than 4. For example, a 4-term error model may describe a single port. As another example, an 8-term error model may describe two ports, for example wherein one of the two ports is a driving port (i.e. is forwarding a signal to an external electronic device such as the device under test) and the other one of the two ports is a receiving port (i.e. is receiving a signal from an external electronic device such as the device under test). However, it is to be understood that any other suitable error model may be used.

According to another aspect of the present disclosure, the error model, for example, is a two-port error model. Therein, one port of the error model may be associated with the signal generator circuit and/or the signal analysis circuit, while the other port of the error model may be associated with the reference plane. The error model describes transmissivity, reflectivity, and/or directivity properties within a portion of the measurement system modeled by the error model, namely a portion of the measurement system between the signal generator circuit and/or the signal analysis circuit and the reference plane.

In another embodiment, the error parameters are indicative of transmissivity, reflectivity properties, and/or directivity of the measurement system obtained by calibration measurements performed by the signal generator circuit. In other words, the error terms of the error model have been determined using the signal generator circuit as a calibration source.

In an embodiment, any suitable calibration technique may be used in order to determine the error parameters. For example, a set of different calibration standards may be consecutively connected to the DUT connector at the reference plane, and corresponding measurements may be performed for each of the different calibration standards.

In a certain example, the set of calibration standards may comprise an “open” calibration standard, a “short” calibration standard, and a “matched” calibration standard (also known as “load” calibration standard). Thus, the calibration method used may be an OSM-calibration, which is also known as SOL-calibration.

Another aspect of the present disclosure provides that the measurement system further comprises, for example, an amplifier circuit. In an embodiment, the amplifier circuit is provided downstream of the signal generator circuit and upstream of the DUT connector. The amplifier circuit is configured to amplify the RF test signal. In other words, the amplifier circuit is located between the signal generator circuit and the DUT connector.

In order to set the desired reflection coefficient at the reference plane, a signal level of the RF test signal exceeding a maximum output level of the signal generator circuit may be necessary, i.e. the maximum output level of the signal generator may be insufficient. The amplifier circuit allows to amplify the RF test signal to the necessary signal level for presenting the desired reflection coefficient to the device under test at the reference plane.

In an embodiment, the amplifier circuit may be provided separately from the signal generator circuit. For example, the amplifier circuit may be integrated on a separate integrated circuit board, e.g. on a card, that can be inserted into a measurement instrument comprising the signal generator circuit. In other words, the measurement instrument may be retrofitted with the amplifier circuit by inserting the integrated circuit board comprising the amplifier circuit.

In an embodiment, the control circuit is configured to set an amplification factor to be applied by the amplifier circuit based on the digitized measurement signal, based on the known error parameters, and/or based on the desired reflection coefficient. In an embodiment, the amplification factor may be set such that the desired reflection coefficient is presented to the device under test at the reference plane.

In an embodiment, the measurement system further comprises a switching circuit configured to selectively couple the amplifier circuit into a signal path between the signal generator circuit and the DUT connector or to bypass the amplifier circuit. Accordingly, the amplifier circuit may be bypassed by the switching circuit if the maximum output level of the signal generator circuit is sufficient for presenting the desired reflection coefficient to the device under test. If the maximum output level of the signal generator circuit is insufficient for presenting the desired reflection coefficient to the device under test, the amplifier circuit may be coupled into the signal path between the signal generator circuit and the DUT connector by the switching circuit.

According to an aspect of the present disclosure, the measurement system further comprises, for example, a directional coupling unit. In an embodiment, the directional coupling unit is connected to the DUT connector, the signal analysis circuit, and the signal generator circuit. In an embodiment, the directional coupling unit is configured to forward the RF test signal from the signal generator circuit to the DUT connector, such that the RF test signal is applied to the device under test at the reference plane. Further, the directional coupling unit is configured to forward the output signal of the device under test from the DUT connector to the signal analysis circuit.

In an embodiment, the directional coupling unit may comprise an electric connection connecting the DUT connector and the signal analysis circuit, or an electric connection connecting the DUT connector and the signal generator circuit.

In an embodiment, the directional coupling unit may comprise the electric connection connecting the DUT connector and the signal analysis circuit, while an electromagnetic coupling is provided between the DUT connector and the signal generator circuit (but no electric connection between the DUT connector and the signal generator circuit). In this configuration, the signal-to-noise ratio (SNR) of the measurement signal is enhanced, as the direct electric connection typically causes less attenuation than the electromagnetic coupling.

Alternatively, the directional coupling unit may comprise the electric connection connecting the DUT connector and the signal generator circuit, while an electromagnetic coupling is provided between the DUT connector and the signal analysis circuit (but no electric connection between the DUT connector and the signal analysis circuit). In this configuration, the SNR of the RF test signal transmitted to the reference plane is enhanced, as the direct electric connection typically causes less attenuation than the electromagnetic coupling.

A further aspect of the present disclosure provides that the directional coupling unit, for example, is switchable between two operational modes, wherein the directional coupling unit comprises an electric connection connecting the DUT connector and the signal analysis circuit in a first operational mode, and wherein the directional coupling unit comprises an electric connection connecting the DUT connector and the signal generator circuit in a second operational mode. Accordingly, the measurement system is switchable between different operational modes providing high SNR for the measurement signal or for the RF test signal.

In an embodiment, the measurement system further comprises an input circuit, wherein the input circuit is configured to receive a user input regarding the desired reflection coefficient. Accordingly, a user may set the desired reflection coefficient via the input circuit.

In an embodiment, the input circuit may comprise a user interface, for example a graphical user interface, and appropriate input means, such as a keyboard, a computer mouse, buttons, a touch-sensitive display or any other suitable type of input means.

In an example, the input circuit may be a network circuit that is configured to receive the user input via a network, for example via a local area network, a wide area network, and/or via the internet. For example, the input circuit may receive the user input as standard commands for programmable instruments (SCPI).

In an embodiment, the input circuit may further be configured to forward the user input regarding the desired reflection coefficient to the control circuit.

In another embodiment, the measurement system comprises a measurement instrument, wherein the measurement instrument comprises the signal generator circuit, the signal analysis circuit, and/or the DUT connector.

In an embodiment, the measurement instrument may further comprise the directional coupling unit described above, the amplifier circuit described above, and/or the input circuit described above.

For example, the measurement instrument may be a vector network analyzer, a signal analyzer, a spectrum analyzer, or an oscilloscope. However, it is to be understood that the measurement instrument may be established as any other suitable type of measurement instrument.

Embodiments of the present disclosure further provide an active load pull measurement method. In an embodiment, the active load pull measurement method comprises receiving an output signal of a device under test; receiving, by a signal analysis circuit, a measurement signal corresponding to the output signal; digitizing, by the signal analysis circuit, the measurement signal, thereby obtaining a digitized measurement signal; determining, by a control circuit, an RF test signal to be generated based on the digitized measurement signal, based on known error parameters of an error model of the measurement system, and based on a desired reflection coefficient at a reference plane associated with the device under test, wherein the error model describes transmissivity, reflectivity, and/or directivity properties of the measurement system with respect to the reference plane; controlling, by the control circuit, a signal generator circuit to generate the determined RF test signal; and applying the RF test signal to the device under test.

The measurement system described above, for example the measurement system according to any one of the embodiments described above, may be configured to perform the active load pull measurement method.

Regarding the further advantages and properties of the active load pull measurement method, reference is made to the explanations given above with respect to the measurement system, which also hold for the active load pull measurement method and vice versa.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a measurement system according to an embodiment of the present disclosure;

FIG. 2 schematically shows a measurement system according to another embodiment of the present disclosure;

FIG. 3 shows a flow chart of an active load pull measurement method according to an embodiment of the present disclosure; and

FIG. 4 shows an error model describing a portion of the measurement system of FIG. 1 or 2.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

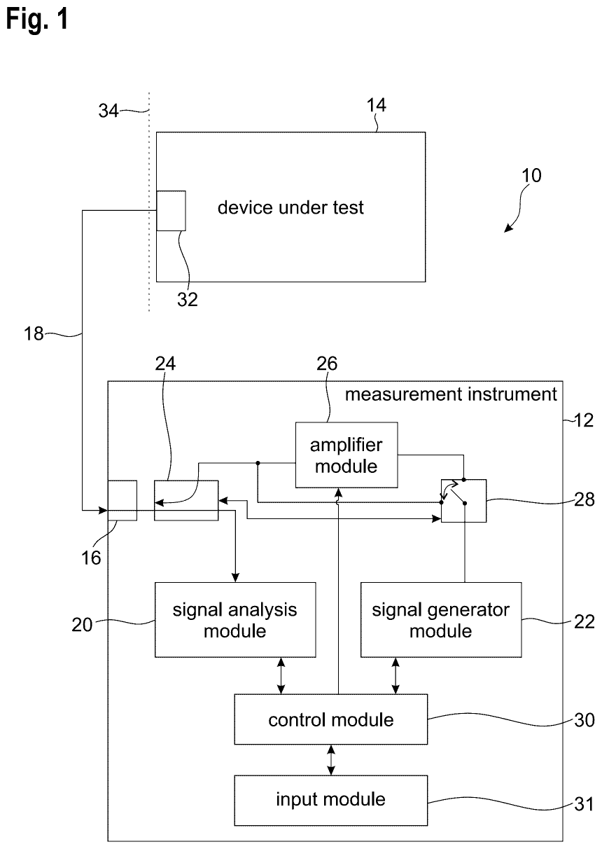

FIG. 1 schematically shows a measurement system 10 comprising a measurement instrument 12 that is configured to perform active load pull measurements on a device under test 14. In the example embodiment shown in FIG. 1, the measurement instrument 12 may be established as a signal analyzer, as a spectrum analyzer, or as an oscilloscope comprising a single DUT connector 16 that is connected to the device under test 14 via a cable 18. However, it is to be understood that the measurement instrument 12 may be established as any other suitable type of measurement instrument comprising one or more ports, such as a vector network analyzer, a signal analyzer, a spectrum analyzer, or an oscilloscope having two or more ports.

Without restriction of generality, the example embodiment shown in FIG. 1 is described hereinafter. As shown in FIG. 1, the measurement instrument comprises a signal analysis circuit 20 and a signal generator circuit 22 that are each connected to the DUT connector 16. In general, the signal analysis circuit 20 is configured to digitize and analyze received signals, as will be described in more detail below. For example, the signal analysis circuit 20 may be or comprise a vector signal analyzer. The signal generator circuit 22 is configured to generate RF test signals, as will be described in more detail below. For example, the signal generator circuit 22 may be or comprise a vector signal generator and/or an arbitrary waveform generator.

The signal analysis circuit 20 and the signal generator circuit 22 are each connected to the DUT connector 16 via a directional coupling unit 24. Therein, the directional coupling unit 24 is configured to forward an output signal of the device under test 14 received by the DUT connector 16 to the signal analysis circuit 20. The directional coupling unit 24 is further configured to forward an RF test signal generated by the signal generator circuit 22 to the DUT connector 16, such that the RF test signal is forwarded to the device under test 14 via the DUT connector 16 and the cable 18.

In the example embodiment shown in FIG. 1, the directional coupling unit 24 comprises an electric connection connecting the DUT connector 16 and the signal analysis circuit 20, as well as an electromagnetic coupling between the DUT connector 16 and the signal generator circuit 22.

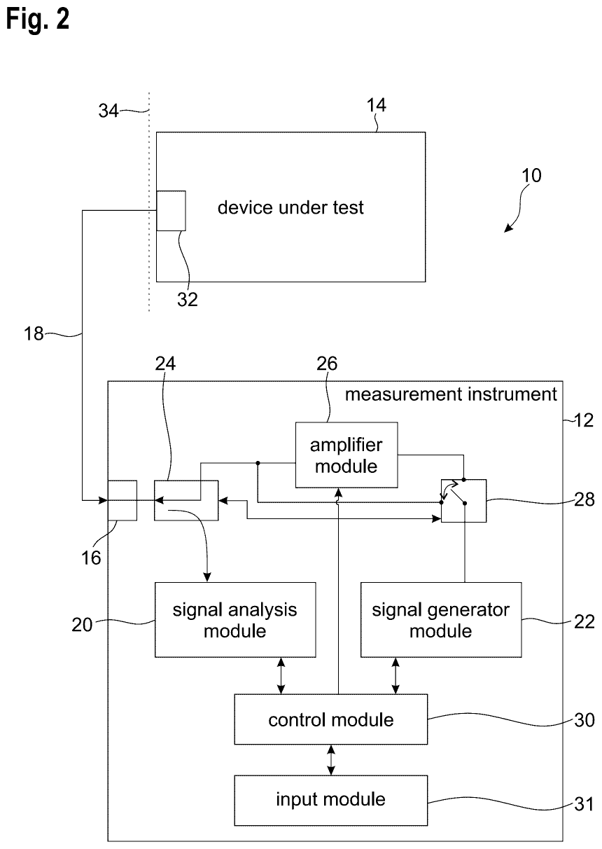

Alternatively, as is illustrated in FIG. 2, the directional coupling unit 24 may comprise an electric connection connecting the DUT connector 16 and the signal generator circuit 22, as well as an electromagnetic coupling between the DUT connector 16 and the signal analysis circuit 20.

Optionally, an amplifier circuit 26 may be provided between the signal generator circuit 22 and the directional coupling unit 24, wherein the amplifier circuit 26 is configured to amplify the RF test signal generated by the signal generator circuit 22 by an adjustable amplification factor.

An optional switching circuit 28 may be provided. The switching circuit 28 is configured to selectively couple the amplifier circuit 26 into a signal path between the signal generator circuit 22 and the DUT connector 16 or to bypass the amplifier circuit 26.

In an embodiment, the amplifier circuit 26 and/or the switching circuit 28 may be provided separately from the signal generator circuit 22. For example, the amplifier circuit 26 and/or the switching circuit 28 may be integrated on a separate integrated circuit board, e.g. on a card, that can be inserted into the measurement instrument 12. Accordingly, the measurement instrument 12 can be retrofitted with the amplifier circuit 26 and/or with the switching circuit 28.

In an embodiment, the measurement instrument 12 further comprises a control circuit 30 that is connected to the signal analysis circuit 20 and the signal generator circuit 22. Optionally, the control circuit 30 may be connected to the directional coupling unit 24, the amplifier circuit 26, and/or the switching circuit 28. In an embodiment, the control circuit 30 may be configured to control the directional coupling unit 24 to switch between the two operational modes shown in FIGS. 1 and 2, respectively.

In the first operational mode shown in FIG. 1, the directional coupling unit 24 comprises the electric connection connecting the DUT connector 16 and the signal analysis circuit 20. In the second operational mode shown in FIG. 2, the directional coupling unit 24 comprises the electric connection connecting the DUT connector 16 and the signal generator circuit 22.

Alternatively or additionally, the control circuit 30 may be configured to adapt the amplification factor of the amplifier circuit 26. Alternatively or additionally, the control circuit 30 may be configured to control the switching circuit 28 to couple the amplifier circuit 26 into the signal path between the signal generator circuit 22 and the DUT connector 16, or to bypass the amplifier circuit 26.

The further functionality of the control circuit 30 will be described in more detail below.

In an embodiment, the measurement instrument 12 may further comprise an input circuit 31 that is configured to receive a user input. For example, the input circuit 31 may comprise a user interface, for example a graphical user interface, and appropriate input means, such as a keyboard, a computer mouse, buttons, a touch-sensitive display or any other suitable type of input means.

In another example, the input circuit 31 may be a network circuit that is configured to receive the user input via a network, for example via a local area network, a wide area network, and/or via the internet. For example, the input circuit 31 may receive the user input as standard commands for programmable instruments (SCPI).

In any case, the input circuit 31 is connected with the control circuit 30, such that the user input received by the input circuit 31 is forwarded to the control circuit 30.

In an embodiment, the device under test 14 comprises an output port 32 that is connected to the DUT connector 16 via the cable 18. In an embodiment, the device under test 14 is connected to the cable at a reference plane 34 that is located at an end of the cable 18 facing away from the DUT connector 16.

In general, the device under test 14 is configured to generate an output signal that is forwarded to the DUT connector 16 via the output port 32 and the cable 18. For example, the device under test 14 may be a mobile communication device, such as a smartphone or a tablet.

While the device under test 14 is shown to be a single-port device in FIGS. 1 and 2, it is to be understood that the device under test 14 may likewise be established as a multiport device.

For example, the device under test 14 may be configured to receive an input signal via an input port, and to process the received input signal, thereby generating the output signal. In a certain example, the device under test 14 may be an amplifier, a mixer, a filter, or any other type of electronic multiport device.

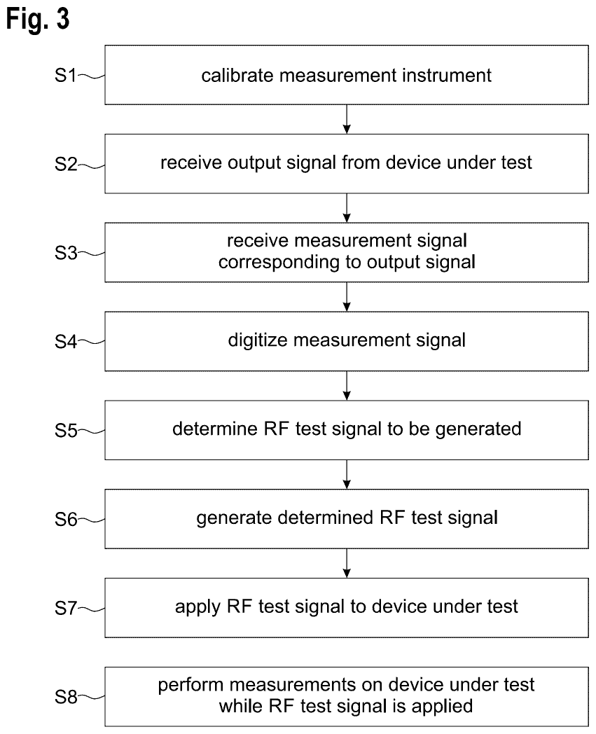

In an embodiment, the measurement system 10, for example the measurement instrument 12, is configured to perform an active load pull measurement method, an example of which is described hereinafter with reference to FIG. 3.

If a calibration of the measurement instrument 12 has not yet been performed, the measurement instrument 12 is calibrated, thereby determining error parameters of an error model (step S1).

Any suitable calibration technique may be used in order to determine the error parameters. For example, a set of different calibration standards may be consecutively connected to the DUT connector at the reference plane, and corresponding measurements may be performed for each of the different calibration standards.

In a certain example, the set of calibration standards may comprise an “open” calibration standard, a “short” calibration standard, and a “matched” calibration standard (also known as “load” calibration standard). Thus, the calibration method used may be an OSM-calibration, which is also known as SOL-calibration.

During the calibration, the signal generator circuit 22 is used as a calibration source, i.e. an RF test signal used for the calibration is generated by the signal generator circuit 22.

In general, the error model or the error parameters of the error model describe reflectivity, transmissivity, and/or directivity properties of a portion of the measurement system 10 between the reference plane 34 on one hand and the signal analysis circuit 20 and the signal generator circuit 22 on the other hand.

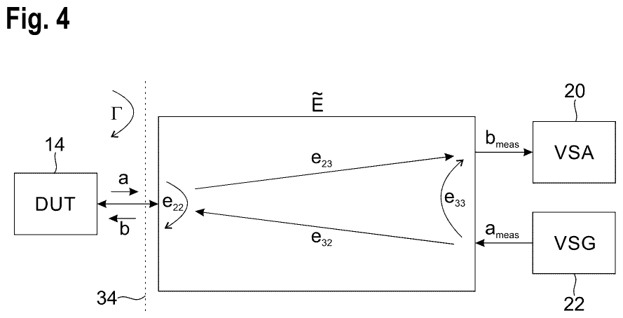

FIG. 4 shows an example error model. In this case, the multi-port error model is a 2-port error model with four error parameters e₂₂, @33, @32, and e₂₃, i.e. a 4-term error model. However, it is to be understood that any other suitable multi-port error model may be used. In an embodiment, the multi-port error model may be any suitable n-term error model comprising n error parameters.

The error terms e₂₂, @33, e₃₂, and e₂₃ describe a reflection of the hardware components of the portion of the measurement system 10 described by the error model (also called “load match”), a transmission between the signal generator circuit 22 and the signal analysis circuit 20 (also called “directivity”), a transmission between the reference plane 34 and the signal analysis circuit 20 (also called “forward tracking”), and a transmission between the signal generator circuit 22 and the reference plane 34 (also called “reverse tracking”), respectively.

The multi-port error model can be expressed as a matrix

$$\tilde{E} = ( \begin{matrix}{e}_{22} & {e}_{23} \\ {e}_{32} & {e}_{33}\end{matrix} ) .$$

An output signal is received from the device under test (step S2).

In FIG. 4, the output signal of the device under test 14 is denoted as “a”, i.e. the signal “a” corresponds to the output signal of the device under test 14 at the reference plane 34.

A measurement signal corresponding to the output signal is received by the signal analysis circuit 20 (step S3).

In FIG. 4, the measurement signal is denoted as “bₘₑₐₛ”.

The output signal a is forwarded to the signal analysis circuit 20 via the cable 18, the DUT connector 16, and the directional coupling unit 24, such that the output signal is altered due to the reflectivity, transmissivity, and directivity properties of the cable 18, the DUT connector 16, and the directional coupling unit 24.

Thus, the measurement signal bₘₑₐₛ at the signal analysis circuit 20 is in general different from the output signal a at the reference plane 34.

The measurement signal bₘₑₐₛ is digitized by the signal analysis circuit 20, thereby obtaining a digitized measurement signal (step S4).

The digitized measurement signal is then forwarded to the control circuit 30.

An RF test signal aₘₑₐₛ to be generated by the signal generator circuit 22 is determined by the control circuit 30 based on the known error parameters of the error model, and based on a desired reflection coefficient Γ at the reference plane 34 (step S5).

The desired reflection coefficient Γ describes an actual reflection coefficient presented to the device under test 14 at the reference plane 34, i.e. including the active load pull described hereinafter. It is emphasized that the desired reflection coefficient is not equal to the load match e₂₂.

In an embodiment, the desired reflection coefficient Γ may be received from a user via the input circuit 31 and may be forwarded to the control circuit 30. In other words, the user may set the desired reflection coefficient via the input circuit 31.

The RF test signal aₘₑₐₛ to be generated can be determined as described hereinafter.

As the error parameters of the error model \tilde{E} are known, the output signal a received from the device under test 14 at the reference plane 34 can be determined based on the digitized measurement signal, i.e. based on the measurement signal bₘₑₐₛ, and based on the known error parameters e₂₂, e₃₃, e₃₂, and e₂₃.

The RF test signal b to be applied to the device under test 14 at the reference plane 34 is given by b=Γ·a, wherein Γ and a are already known.

As the error parameters of the error model \tilde{E} are known, the RF test signal aₘₑₐₛ to be generated can then be determined based on b=Γ·a and based on the error parameters of the error model.

In an embodiment, the determined RF test signal aₘₑₐₛ may be a modulated signal.

The signal generator circuit 22 is controlled by the control circuit 30 to generate the determined RF test signal aₘₑₐₛ (step S6).

The RF test signal aₘₑₐₛ is forwarded to the reference plane 34 via the directional coupling unit 24, the DUT connector 16, and the cable 18.

If a maximum output level of the signal generator circuit is insufficient to obtain the RF test signal b at the reference plane 34, the RF test signal aₘₑₐₛ generated by the signal generator circuit 22 may be amplified by the amplifier circuit 26. In an embodiment, the control circuit 30 may control the amplifier circuit 26 to set an appropriate amplification factor.

Alternatively or additionally, the control circuit 30 may control the switching circuit 28 to couple the amplifier circuit 26 into the signal path between the signal generator circuit 22 and the DUT connector 16.

The RF test signal b corresponding to the generated RF test signal aₘₑₐₛ is applied to the device under test 14 at the reference plane 34 (step S7).

Accordingly, the desired reflection coefficient Γ is presented to the device under test 14 at the reference plane 34. In other words, a desired impedance is presented to the device under test 14 at the reference plane 34.

Further measurements may be performed on output signals received from the device under test 14 while the RF test signal is applied to the device under test (step S8).

These further measurements may be performed by the signal analysis circuit 20.

Accordingly, a performance of the device under test 14 can be assessed while the desired reflection coefficient corresponding to the desired impedance is presented to the device under test 14. In other words, active load pull measurements may be performed.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the measurement system 10 referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A measurement system for active load pull testing, wherein the measurement system comprises a signal analysis circuit, a signal generator circuit, a control circuit, and a DUT connector,
wherein the DUT connector is connectable to a device under test in order to receive an output signal of the device under test,
wherein the signal analysis circuit is connected to the DUT connector, such that the signal analysis circuit receives a measurement signal corresponding to the output signal,
wherein the signal generator circuit is configured to generate a radio frequency, RF, test signal,
wherein the signal generator circuit is connected to the DUT connector, such that the RF test signal is applied to the device under test,
wherein the signal analysis circuit is configured to digitize the measurement signal, thereby obtaining a digitized measurement signal, and
wherein the control circuit is configured to control the signal generator circuit to generate the RF test signal based on the digitized measurement signal, based on known error parameters of an error model of the measurement system, and based on a desired reflection coefficient at a reference plane associated with the device under test, wherein the error model describes transmissivity, reflectivity, and/or directivity properties of the measurement system with respect to the reference plane.

2. The measurement system of claim 1, wherein the RF test signal is a modulated signal.

3. The measurement system according to claim 1, wherein the error model is an n-term error model.

4. The measurement system of claim 3, wherein the error model is a 4-term error model or an 8-term error model.

5. The measurement system according to claim 1, wherein the error model is a two-port error model.

6. The measurement system according to claim 1, wherein the error parameters are indicative of transmissivity, reflectivity, and/or directivity properties of the measurement system obtained by calibration measurements performed by the signal generator circuit.

7. The measurement system according to claim 1, further comprising an amplifier circuit, wherein the amplifier circuit is provided downstream of the signal generator circuit and upstream of the DUT connector, and wherein the amplifier circuit is configured to amplify the RF test signal.

8. The measurement system of claim 7, wherein the control circuit is configured to set an amplification factor to be applied by the amplifier circuit based on the digitized measurement signal, based on the known error parameters, and/or based on the desired reflection coefficient.

9. The measurement system of claim 7, further comprising a switching circuit, wherein the switching circuit is configured to selectively couple the amplifier circuit into a signal path between the signal generator circuit and the DUT connector or to bypass the amplifier circuit.

10. The measurement system according to claim 1, further comprising a directional coupling unit, wherein the directional coupling unit is connected to the DUT connector, the signal analysis circuit, and the signal generator circuit.

11. The measurement system of claim 10, wherein the directional coupling unit comprises an electric connection connecting the DUT connector and the signal analysis circuit, or an electric connection connecting the DUT connector and the signal generator circuit.

12. The measurement system of claim 10, wherein the directional coupling unit is switchable between two operational modes, wherein the directional coupling unit comprises an electric connection connecting the DUT connector and the signal analysis circuit in a first operational mode, and wherein the directional coupling unit comprises an electric connection connecting the DUT connector and the signal generator circuit in a second operational mode.

13. The measurement system according to claim 1, further comprising an input circuit, wherein the input circuit is configured to receive a user input regarding the desired reflection coefficient.

14. The measurement system according to claim 1, further comprising a measurement instrument, wherein the measurement instrument comprises the signal generator circuit, the signal analysis circuit, and/or the DUT connector.

15. The measurement system of claim 14, wherein the measurement instrument is a vector network analyzer, a signal analyzer, a spectrum analyzer, or an oscilloscope.

16. An active load pull measurement method, comprising:
receiving an output signal of a device under test;
receiving, by a signal analysis circuit, a measurement signal corresponding to the output signal;
digitizing, by the signal analysis circuit, the measurement signal, thereby obtaining a digitized measurement signal;
determining, by a control circuit, an RF test signal to be generated based on the digitized measurement signal, based on known error parameters of an error model of the measurement system, and based on a desired reflection coefficient at a reference plane associated with the device under test, wherein the error model describes transmissivity, reflectivity, and/or directivity properties of the measurement system with respect to the reference plane;
controlling, by the control circuit, a signal generator circuit to generate the determined RF test signal; and
applying the RF test signal to the device under test.
